(19) United States
(12) Patent Application Publication
(10) Pub. No.: US 2012/0153978 A1
(43) Pub. Date: Jun. 21, 2012

(54) RIBBON TERMINAL CONNECTING APPARATUS

(75) Inventors: Mitsuhiro Shimotomai, Aichi (JP); Sumito Takeshita, Aichi (JP)

(73) Assignee: NISSHINBO MECHATRONICS INC., TOKYO (JP)

(21) Appl. No.: 13/391,624

(22) PCT Filed: Aug. 26, 2010
(86) PCT No.: PCT/JP2010/064982

§ 371 Date: Feb. 22, 2012

(30) Foreign Application Priority Data
Aug. 26, 2009 (JP) 2009-195990

(51) Int. Cl. G01R 31/26

(52) U.S. Cl. 324/750.19

(57) ABSTRACT

A ribbon terminal connecting apparatus for connecting a ribbon terminal of a photovoltaic device panel to an inspection apparatus terminal automatically when inspecting or measuring a photovoltaic device panel is provided. The ribbon-shaped terminal connecting apparatus includes a stand-up means, a base pressing means, a terminal connecting means and a moving means. The stand-up member of the stand-up means is lowered onto and contacted against the backing material of the photovoltaic device panel. The base portion of the ribbon terminal extended from the backing material is held down by the pressing means for pressing down on the base portion of the ribbon terminal. The moving means moves the stand-up member so that a leading edge of the ribbon terminal extending across the backing material is placed on the stand-up member. The terminal connecting means connects the terminal of the inspection apparatus to the ribbon terminal placed on the stand-up member.

### BACKGROUND OF THE INVENTION

1. Field of the Invention

The present invention relates to an ribbon terminal connecting apparatus for connecting a ribbon terminal extended from a rear face of a backing material of a photovoltaic device panel to an inspection apparatus terminal automatically when measuring a photovoltaic device panel.

2. Description of Related Art

FIG. 16A and FIG. 16B show a general structure of a photovoltaic device panel. FIG. 16A is a planar view. In FIG. 16A, photovoltaic cells in the interior of the photovoltaic device panel are clearly illustrated. FIG. 16B is a cross-sectional view of FIG. 16A.

As shown in FIG. 16A, the photovoltaic device panel 200 is configured as follows: a string 5 which is formed by plural square shaped photovoltaic cells connected in series by lead wires 9; the plural columns of strings are connected by lead wire 9.

In addition, as shown in FIG. 16B, the configuration of the photovoltaic device panel in sectional structure is formed by disposing the plural columns of strings 25 sandwiched by filling members 3 and 4 between a back side member 2 disposed in an upper side and a transparent cover glass 1 disposed in a lower side.

Polyethylene resins or the like, for instance, are used for the backing material 2 and EVA (polyethylene vinyl acetate, EVA) resins or the like are used for the filling members 3 and 4. As described above, the string 5 is formed by photovoltaic cells 8 connected between electrodes 6 and 7 by the lead wire 9.

The photovoltaic device panel 200 can be obtained by piling constitutional members as described above, and laminating. The laminating process is performed by pressing with force under heating in vacuum to cross-link the EVA resin with a laminator or the like.

In addition, a kind of photovoltaic devices, which is generally called as a thin film-type, may be employed as the photovoltaic device panel 200.

For example, a typical structure of these thin film-type photovoltaic devices are obtained in the following way: depositing a power generating element comprised of a transparent electrode, a semiconductor and a rear back electrode via vacuum evaporation on the transparent cover glass disposed at the lower side; disposing the transparent cover glass at the lower side; covering the photovoltaic devices elements disposed on the glass with the filling members; and covering the filling members with the back side member; and laminating the piled constructional members with a laminator.

Such thin-film photovoltaic device panels 200 only replaces crystalline cells with the aforementioned power generating elements, and the basic sealing structure is identical to the case of the crystalline cells in the aforementioned description.

As shown in FIG. 16B, ribbon terminals R1 and R2 (hereinafter collectively “R”) are provided to edges of lead wire 9 as a positive electrode and lead wire 9 as a negative electrode, and the ribbon terminals are extended from the backing material to an outside surface of the photovoltaic device panel 200. In FIG. 16A, R1 and R2 are temporally drawn as extending and lying in the opposite direction to that in FIG. 16B for convenience of drawing.

Various inspections are performed to thus photovoltaic device panel 200 in its manufacturing process. Various inspections are as follows: whether the photovoltaic device panel has a predetermine power generation capacity; whether there are no defects on photovoltaic cells 8 which configure the photovoltaic device panel; or the like. As for the inspection of power generating capacity, there is a method for measuring voltage and current generated between the ribbon terminals R1 and R2 by irradiating a certain power of light to the photovoltaic device panel (For example, Patent Document 1). Moreover, there is a method for inspecting defects by applying current to the photovoltaic device panel 200 in the forward direction, making each photovoltaic cells 8 emit EL(electro-luminescence) light and analyzing the portion where not emitting (For example, Patent Document 2).

[Patent Document 1] Japanese Unexamined Patent Publication No. 2007-088419

[Patent Document 2] International Publication No. WO/2006/059615

### SUMMARY OF THE INVENTION

When inspecting or measuring as described above, ribbon terminals R1 and R2, which are extended from a backing material of a photovoltaic device panel to an outside surface of the photovoltaic device panel 200, is connected to inspection apparatus terminals for various inspections. Conventionally, these ribbon terminals has been connected by hand. In inspecting or measuring photovoltaic device panels, if operation of connecting these ribbon terminals can be automated, whole automation of inspections and measurements can be realized. In the present, however, since the terminal connecting process is still carried out by hand, whole automation of inspections or measurements is not realized. Consequently, this has caused a manufacturing cost of photovoltaic device panels to increase.

However, when connecting ribbon terminals extended from the photovoltaic device panel to inspection apparatus terminals automatically, some problems such as below described may occur. When a measuring object 200 is a crystalline photovoltaic device panel, polycrystalline silicon cells are used for photovoltaic cells 8 inside the photovoltaic device panel and its thickness is very thin. Therefore, damages or cracks to the photovoltaic cells may occur due to a mechanical pressing force applying to the photovoltaic cells when a connecting member is contacting against the photovoltaic device panel during the automatic operation that ribbon terminals is connected to inspection apparatus terminals automatically. Consequently, the photovoltaic device panel may become defective.

Considering these problems, it is an objective of the present invention to provide a ribbon terminal connecting apparatus for a photovoltaic device panel to make ribbon terminals of the photovoltaic device panel to inspection apparatus terminals connect automatically when inspecting or measuring the photovoltaic device panel.

To realize the above-described objective, one configuration of the present invention of a ribbon terminal connecting apparatus for a photovoltaic device panel is as follows. The ribbon terminal connecting apparatus includes: the stand-up means for standing up the ribbon terminal extending across a backing material of a photovoltaic device panel; the base pressing, means for pressing a base portion of a ribbon-shaped terminal; the terminal connecting means for connecting the inspection apparatus terminal; and the moving means for moving the stand-up member. The stand-up member of the stand-up means is lowered onto and contacted against the backing material of the photovoltaic device panel. The base portion of the ribbon terminal extended from the backing material is held down by the pressing means for pressing down on the base portion of the ribbon terminal. The moving means moves the stand-up member so that a leading edge of the ribbon terminal extending across the backing material is placed on the stand-up member. The terminal connecting means connects the terminal of the inspection apparatus to the ribbon terminal placed on the stand-up member.

The following configuration may be employed as the above described configuration of ribbon terminal connecting apparatus for a photovoltaic device panel.

The ribbon terminal connecting apparatus may be also configured as below:

when the terminal connecting means connects the terminal of the inspection apparatus to the ribbon-shaped terminal placed on the stand-up member, the stand-up member is raised and separated from a surface of the backing material of the photovoltaic device panel; a control means is provided to the stand-up member for detecting a position of the surface of the backing material, wherein, when the stand-up member is lowered onto the backing material of the photovoltaic device panel, the control means detects the position of the surface of the backing material and adjusts the pressure with which the stand-up member contacts the backing material;

when the stand-up member of the stand-up means is lowered onto the backing material of the photovoltaic device panel, the control means of the stand-up member detects the position of the surface of the backing material and lowers the stand-up member toward the backing material while maintaining a gap between the stand-up member and the surface of the backing material, the base portion of the ribbon-shaped terminal, the moving means moves the stand-up member so that a leading edge of the ribbon-shaped terminal extending across the backing material is placed on the stand-up member, and the terminal connecting means connects the terminal of the inspection apparatus to the ribbon-shaped terminal placed on the stand-up member;

a lowering means for lowering the stand-up member onto the photovoltaic device panel having a first lowering unit and a second lowering unit, wherein, after the first lowering unit lowers the stand-up member to a certain distance from the surface of the backing material and stops thereat, the second lowering unit lowers the stand-up member onto the backing material of the photovoltaic device panel;

the second lowering unit comprises reduction means for reducing the force of the stand-up means when the stand-up member is lowered onto the backing material of the photovoltaic device panel;

the moving means is provided with a measuring means for measuring a moved distance to decide whether or not the ribbon terminal is placed on the stand-up member when the moving means moves the stand-up member so that a leading edge of the ribbon terminal extending across the backing material is placed on the stand-up member;

a suction gripping means for making the ribbon-shaped terminal stand up;

the edge portion of the stand-up member is tapered.

The ribbon terminal is provided to take out electrical output from a photovoltaic device panel. The ribbon terminals are provided in two places extending across the rear face of the backing material of the photovoltaic device panel. When the photovoltaic device panel is disposed on an inspection apparatus, the ribbon terminals are also positioned on predetermined positions against the inspection apparatus. The ribbon terminal connecting apparatus of the present invention includes: the stand-up means for standing the ribbon-shaped terminal up on the backing material; the pressing means for pressing down on the base portion of the ribbon-shaped terminal; the terminal connecting means for connecting the inspection apparatus terminal; moving means for moving the stand-up member. The stand-up member of the stand-up means is lowered onto and contacted against the backing material of the photovoltaic device panel. The base portion of the ribbon terminal extended from the backing material is held down by the pressing means for pressing down on the base portion of the ribbon terminal. Then, the moving means moves the stand-up member so that a leading edge of the ribbon terminal extending across the backing material is placed on the stand-up member. Finally, the terminal connecting means connects the terminal of the inspection apparatus to the ribbon terminal placed on the stand-up member. Therefore, the ribbon terminal of the photovoltaic device panel can surely be connected with the inspection apparatus terminal automatically. Furthermore, the present invention provides automation of the manufacturing process of the photovoltaic device panel.

When the terminal connecting means connects the terminal of the inspection apparatus to the ribbon terminal placed on the stand-up member, the stand-up member is raised and separated from the surface of the backing material of the photovoltaic device panel. Therefore, when connecting the inspection apparatus terminal to the ribbon terminal, no damage occurs to photovoltaic cells because they do not receive any impulsive forces.

The control means is provided to the stand-up member for detecting a position of the surface of the backing material, and when the stand-up member is lowered onto the backing material of the photovoltaic device panel, the control means detects the position of the surface of the backing material and adjusts the pressure with which the stand-up member contacts the backing material. Therefore, although the stand-up member contacts the backing material, no damage occurs to the photovoltaic cells because external force to the photovoltaic device panel is very slight.

The present invention of the ribbon-shaped terminal connecting apparatus includes: the stand-up means for standing the ribbon-shaped terminal up on the backing material; the pressing means for pressing down on a base portion of the ribbon-shaped terminal; the terminal connecting means for connecting the inspection apparatus terminal; the moving means for moving the stand-up member. When the stand-up member of the stand-up means is lowered very close to the backing material of the photovoltaic device panel, the control means of the stand-up member detects the position of the surface of the backing material and lowers the stand-up member toward the backing material while maintaining a gap between the stand-up member and the surface of the backing material, the base portion of the ribbon terminal extended from the backing material is held down by the pressing means for pressing down on the base portion of the ribbon terminal, the moving means moves the stand-up member so that a leading edge of the ribbon terminal extending across the backing material is placed on the stand-up member, and the terminal connecting means connects the terminal of the inspection apparatus to the ribbon terminal placed on the stand-up member. Therefore, the stand-up member is lowered onto the backing material of the photovoltaic device panel within a short time. The time to connect an inspection apparatus terminal shortens. The cycle time for the inspection apparatus decreases.

The lowering means for lowering the stand-up member onto the rear face of the backing material of photovoltaic device panel has the first lowering unit and the second lowering unit. After the first lowering unit lowers the stand-up member to a certain distance from the surface of the backing material and stops thereat, the second lowering unit lowers the stand-up member onto the backing material of the photovoltaic device panel. Therefore, the stand-up member is lowered very close to the rear face of the backing material of the photovoltaic device panel within a short time.

The second lowering unit includes the reduction means for reducing the force of the ascent/descent portion. When the stand-up member is lowered onto the backing material of the photovoltaic device panel by the second lowering unit, although the stand-up member contacts the backing material, no damage occurs to the photovoltaic cell because external force to the photovoltaic device panel is very slight.

The moving means is provided with a measuring means for measuring a moved distance to decide whether or not the ribbon terminal is placed on the stand-up member. Therefore, the moving means moves the stand-up member so that a leading edge of the ribbon terminal extending across the backing material is placed on the stand-up member, and the ribbon terminal is connected surely.

The ribbon terminal connecting apparatus includes the suction gripping means for making the ribbon-shaped terminal stand up. The ribbon terminal is surely placed on the surface of the stand-up member and connected to the inspection apparatus terminal, even if the edge portion of the ribbon-shaped terminal extending across the backing material of the photovoltaic device panel is hardly opened.

Since the edge portion of the stand-up member is tapered, the ribbon terminal is surely connected to the inspection apparatus terminal with making the ribbon terminal extending from the backing material stand up.

Other features and advantages of the present invention will be apparent from the following description when taken in conjunction with the accompanying drawings, in which like reference characters designate similar or identical parts throughout the several views thereof.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an explanatory drawing: the ribbon terminal connecting apparatus of the present invention for photovoltaic device panel is disposed on the inspection apparatus according to the present invention.

FIG. 2 is a planar view of the ribbon terminal connecting apparatus according to the present invention.

FIG. 3 is a front view of the ribbon terminal connecting apparatus according to the present invention.

FIG. 4 is a side view of the ribbon terminal connecting apparatus according to the present invention.

FIG. 5 is a detailed drawing of a ribbon terminal connecting unit of a according to the present invention.

FIG. 6 is an operating explanatory drawing of the ribbon terminal connecting apparatus.

FIG. 7 is an operating explanatory drawing of the ribbon terminal connecting apparatus.

FIG. 8 is an operating explanatory drawing of the ribbon terminal connecting apparatus.

FIG. 9 is an explanatory drawing of the state that the pressing means for the base potion of the ribbon terminal is pressing down the ribbon terminal extended from the backing material.

FIG. 10 is an explanatory drawing of the operation that the ribbon terminal is connected to the inspection apparatus terminal in the third embodiment.

FIG. 11 is an explanatory drawing of another example to realize the operations in the third embodiment.

FIG. 12 is an explanatory drawing of another example to realize the operations in the third embodiment.

FIG. 13 is an explanatory drawing of another example to realize the operations in the third embodiment.

FIG. 14 is an explanatory drawing of another example of the scraper shaped member.

FIG. 15 is an explanatory drawing of the suction gripping means 600.

FIG. 16A and FIG. 16B show a structure of a general photovoltaic device panel. FIG. 16A is a planar view which shows photovoltaic cells inside the photovoltaic device panel. FIG. 16B is a cross-sectional view thereof.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

A detailed description will now be given of illustrative embodiments of the present invention, with reference to the accompanying drawings. In so doing, specific terminology is employed solely for the sake of clarity, and the present disclosure is not to be limited to the specific terminology so selected. It is to be understood that each specific element includes all technical equivalents that operate in a similar manner and achieve a similar result.

### First Embodiment

A detailed description will now be given of illustrative embodiments of the present invention, with reference to the accompanying drawings.

<1> Inspection Apparatus A

The ribbon terminal connecting apparatus is applied to inspection apparatuses such as: solar simulator for measuring I-V characteristics of a photovoltaic device panel; defect inspection apparatus of a photovoltaic cell with EL light; and electricity flow confirming apparatus of a photovoltaic device panel. In the description of this embodiment, the defect inspection apparatus of photovoltaic cells (hereinafter simply “defect inspection apparatus”) with EL light is taken as an example to describe the structure and the operation of the ribbon terminal connecting apparatus according to the present invention.

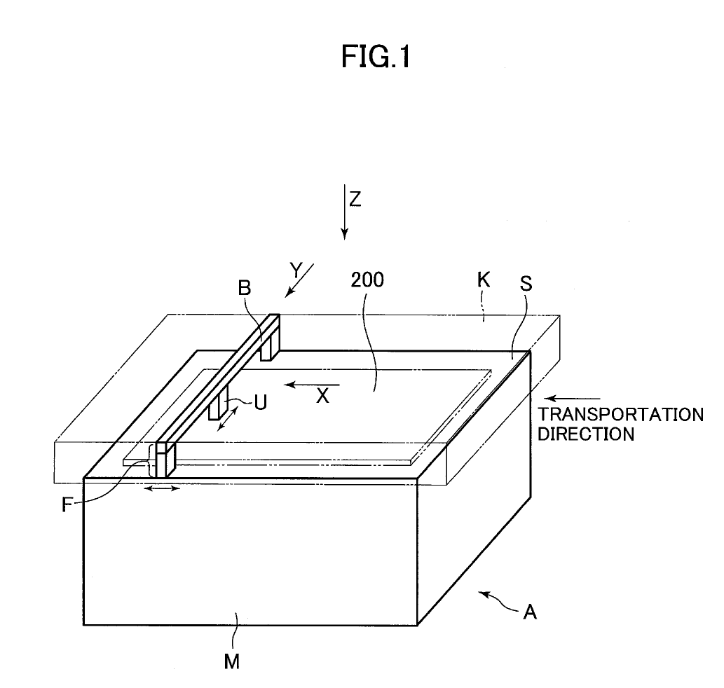

The inspection apparatus A with which the ribbon terminal connecting apparatus is provided thereon includes the box shaped base frame M with the shading cover K on the top surface S as shown in FIG. 1. The door of the shading cover K opens, and the photovoltaic device panel 200 as the object to be measured is transported into the inspection apparatus and positioned. In case of this embodiment, the photovoltaic device panel is transported in the transportation direction shown by the arrow in FIG. 1. Once the photovoltaic device panel is transported into the inspection apparatus, the door closes and an inspection measurement starts. After completing the inspection measurement, the door opens and the photovoltaic device panel is carried out. The present invention of the ribbon terminal connecting apparatus is disposed on the top surface S of the inspection apparatus A under the shading cover as follows. Hereinafter, the shading cover is omitted in the description and the explanatory drawings.

The present invention of the ribbon terminal connecting apparatus, as shown in FIG. 1, is provided on the gate shaped frame F disposed on the top surface S of a defect inspection apparatus. The connecting unit U is provided on the beam B of the gate shaped frame F. The connecting unit U includes: the stand-up means for standing the ribbon terminal up on the backing material as aftermentioned; the pressing means for pressing down on a base portion of the ribbon-shaped terminal; the terminal connecting means for connecting the inspection apparatus terminal. In the accompanying drawings, one connecting unit is disposed for connecting two ribbon terminals. Even though an interval between the two ribbon terminals of the photovoltaic device panel in the orthogonal direction to the transportation direction varies, the connecting unit U is shifted freely. In addition, the gate shaped frame is shifted freely on the top surface S of the inspection apparatus A to cope with the variation of the position of the ribbon terminal of the photovoltaic device panel in the transportation direction of the photovoltaic device panel.

<2> General Structure of the Ribbon Terminal Connecting Apparatus

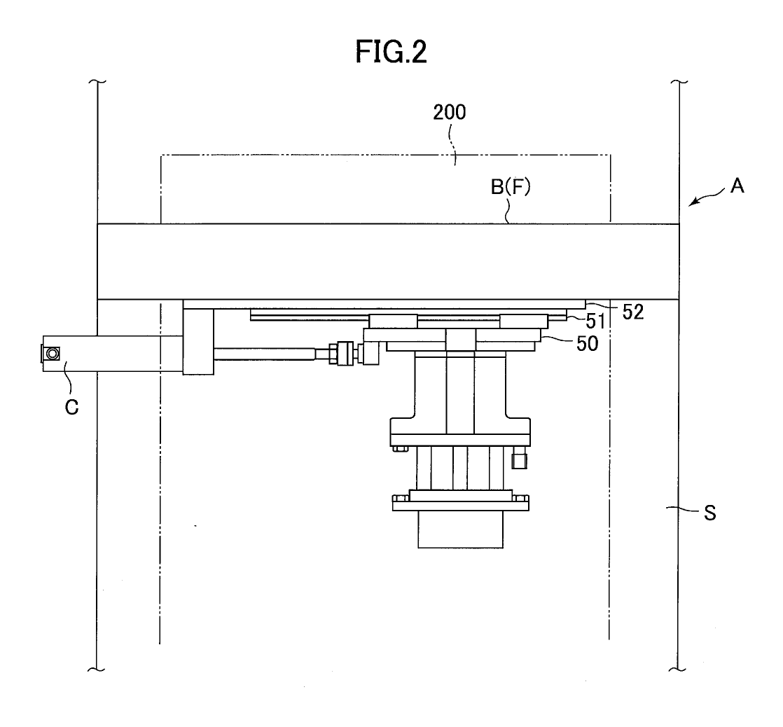

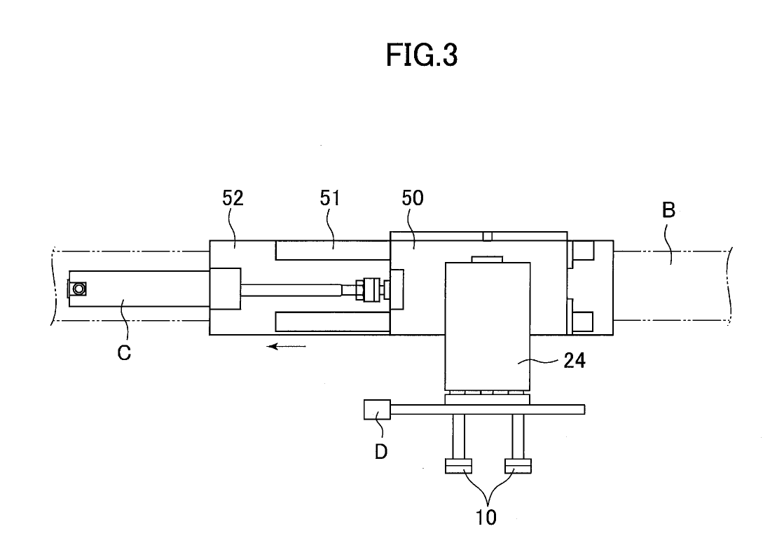

A description is given of the general structure of the ribbon terminal connecting apparatus according to the present invention with reference to FIG. 2, FIG. 3 and FIG. 4. FIG. 2 is a front view seen from the Z direction in FIG. 1 (from above the inspecting apparatus). FIG. 3 is a front view seen from the X direction in FIG. 1. FIG. 4 is a side view seen from the Y direction in FIG. 1. The connecting unit U is disposed on the beam B located on top of the gate shaped frame. As shown in FIG. 4, the connecting unit U includes: the stand-up means 100; the pressing means 300 for pressing the base portion of the ribbon terminal; the connecting means 400 for connecting the inspection apparatus terminal; the shift means for shifting the connecting unit U to Y direction shown in FIG. 1.

Once the photovoltaic device panel 200 is transported into the inspection apparatus A, the sensor D shown in FIG. 3 detects the ribbon terminal of the photovoltaic device panel, and the photovoltaic device panel is positioned to a predetermined position. After that, the cylinder C of the shift means 500 in the connecting unit moves along the arrow direction in FIG. 3 to match the position of the ribbon terminal R with the position of the stand-up member in the direction orthogonal to the transportation direction of the photovoltaic device panel. The two sets of the stand-up unit are disposed in accordance with the interval between two ribbon terminals.

The shift means 500 of the connecting unit is configured as follows: the mounting plate 52 is provided to the beam B of the frame F. The terminal connecting unit is provided to the Frame F; one set of the guide member 51 is provided on the mounting plate 52; the guide member 51 is provided with the base plate 50; the base plate 50 is guided and slid by the guide member and the cylinder C.

<3> Structure of the Stand-Up Means 100

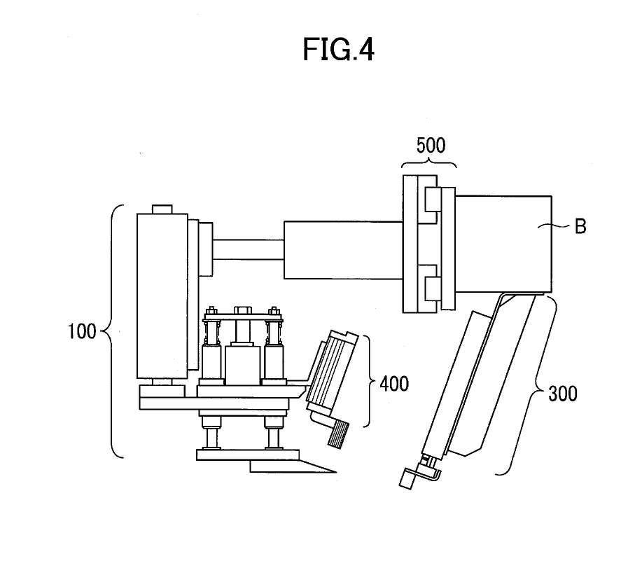

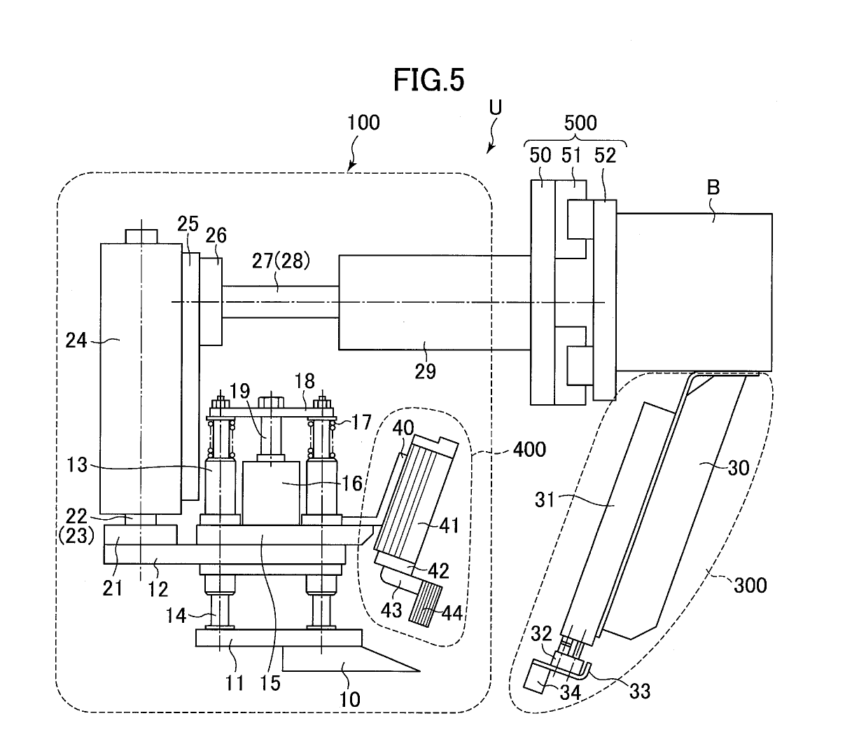

As shown in FIG. 5, the stand-up means 100 is provided with the stand-up member on the tip. In this embodiment, the stand-up means is the scraper shaped member 10 and the tip is tapered. The ribbon terminal extending across a backing material of a photovoltaic device panel is placed on the tapered surface of the scraper shaped member by using each actuator functions provided on the connecting unit.

The ascent/descent operating of the stand-up means 100 is performed by ascent/descent cylinders 16 and 24. In FIG. 5, the scraper shaped member 10 is raised. Firstly, the ascent/descent cylinder 24 is lowered. Then the ascent/descent cylinder 16 is lowered. The scraper shaped member 10 is lowered onto and contacted against the backing material of the photovoltaic device panel 200 (hereinafter it may be described as “land”).

A description is given of the structure of the ascent/descent portion which performs the first ascent/descent operation. The ascent/descent cylinder 24 is attached to the back plate 25. In this embodiment, the cylinder 24 is the cylinder with the guiding function (hereinafter referred to as guide cylinder). The cylinder rod 22 and the guide bar 23 are connected to the end plate 21 of the cylinder. The end plate 21 is connected to the mounting plate 12. The cylinder 16 which performs a second ascent/descent operation is attached to the mounting plate 12 as aftermentioned. The cylinder 24 may not be the guide cylinder. The cylinder 24 may be configured so as to ascend/descend by the guide bar and the cylinder which performs the second ascent/descent operation as aftermentioned.

Secondly, a description is given of the structure of the ascent/descent portion which performs the second ascent/descent operation. The scraper shaped member is fixed to the mounting plate 11. In addition, two guides 13 are provided to the plate 15 on the mounting plate 12. Two guide bars 14 are provided as they slide into the two guides 13. Both ends of the guide bar are fixed to the mounting plate 11 and the end plate 18. The tip of the rod of the cylinder 16 is attached to the end plate 18. Once the cylinder 16 is lowered, the scraper shaped member lands on the surface of a backing material of a photovoltaic device panel. In addition, the spring 17 is provided between the guide 13 and the end plate 18. As the scraper shaped member is lowered, the compressive force generating in the spring increases. The increased compressive force is offset by downward force by air pressure. Therefore, the pressing force is reduced when the scraper shaped member lands on the surface of the backing material of the photovoltaic device panel. Consequently, neither cracks nor damages occur to photovoltaic cells when the scraper shaped member lands on the surface of the backing material of the photovoltaic device panel.

In FIG. 5, the spring is used as the pressing force reduction means. However, it also can be configured as follows. The balancing cylinder having an upper chamber communicated to the atmosphere and a lower chamber supplied with pressurized air may be disposed in parallel to the elevating cylinder 16, and the cylinder rod thereof may be connected to the end plate 18. The counter weight system may be employed although it needs enough space.

Further, the second ascent/descent portion is provided by the same quantity as the ribbon terminal. Two sets are provided in this embodiment. Preferably, they are operated independently. However, one set of ascent/descent portions may be operated for connecting two ribbon terminals.

In addition, a description is given of the configuration to move the scraper shaped member which is lowered onto the surface of the backing material of the photovoltaic device panel 200. The guide cylinder 29 is attached to the base plate 50 of the shift means 500 provided to the beam B on which the ribbon terminal connecting unit U is provided. The end plate 26 is connected to the back plate 25. The cylinder rod 27 and the guide bar 28 of the cylinder 29 are connected to the end plate 26. The back plate 25 is attached to the first ascent/descent cylinder 24 of the scraper shaped member 10. The scraper shaped member moves in a horizontal direction on the surface of the backing material of the photovoltaic device panel 200 by the cylinder 29.

The above-described moving cylinder 29 may be provided with the detecting apparatus which can measure the moving distance. The photovoltaic device panel in the inspection apparatus is positioned by the positioning apparatus. Since each photovoltaic device panel has different slit positions on a backing material, the measuring result is transferred to the control apparatus of the inspection apparatus A after the positions are measured by other apparatuses. Since the moved distance is measured by the detector disposed in the cylinder or the like, it is confirmed by the detector that the ribbon terminal reaches the position on the scraper shaped member. Consequently the moving cylinder stops. The above-described configuration is realized in particular by using the pulse-driven motor cylinder as the cylinder, and the linear encoder as the position confirmation.

<4> Structure of the Pressing Means 300 for Pressing the Base Portion of the Ribbon Terminal

The pressing means 300 presses the base portion of the ribbon terminal base, in other words, the portion of the backing material slit of a photovoltaic device panel where the ribbon terminal is extended from, before the scraper shaped member 10 which lands on the backing material of the photovoltaic device panel moves to the ribbon terminal by using the moving cylinder 29 of a stand-up means. By this configuration, the ribbon-shaped terminal is smoothly placed on the tapered surface of the scraper shaped member without swinging.

As shown in FIG. 5, the pressing means 300 is configured as follows: the ascent/descent cylinder 31 is provided on the bracket 30 fixed to the beam B attached to a shift means 500 of the connecting unit U. The guide cylinder is preferably employed as Cylinder, but Cylinder is not limited to the guide cylinder. The end plate 32 of the guided cylinder has the supportive member 33 whose tip is attached to the base pressing member 34. The pressing means 300 is positioned at right angle with the tapered surface of the scraper shaped member as no collision of the members occurs in the connecting operation of the terminal connecting means 400 which connects the ribbon-shaped terminal placed on the tapered portion of the scraper shaped member 10. FIG. 9 is a magnified view of the ribbon terminal pressed by the pressing member of the pressing means.

Preferably the pressing means is provided by the same quantity as the ribbon terminal and they is operated independently. Two sets are provided in this embodiment. However, one set of the pressing means may be operated for connecting two ribbon terminals. In addition, the pressing member 34 is made of resin block such as urethane which can be easily deformed to apply an uniform pressure to the ribbon terminal.

Further, the pressing means may be attached to the base plate 50 of the moving means 500, unlike the configuration shown in FIG. 5.

<5> Structure of Terminal Connecting Means 400

The terminal connecting means 400 connects the inspection apparatus terminal to the ribbon terminal R placed on the tapered surface of the scraper shaped member 10 whose tip is tapered. As shown in FIG. 5, the terminal connecting means is configured as follows. The bracket 40 is fixed to the mounting plate 15 of the second lowering cylinder 16 of the scraper shaped member 10. The bracket 40 is provided on the ascent/descent cylinder 41. The guide cylinder is preferably employed as Cylinder, but Cylinder is not limited to the guide cylinder. The end plate 42 of the guide cylinder is provided with the supportive member 43 whose tip is attached to the terminal connecting member 44. The terminal connecting means 400, as well as the pressing means 300, is disposed in the direction at right angles to the tapered angle of the scraper shaped member for pressing the tapered tip portion of the ribbon terminal which is placed on the tapered portion of the scraper shaped member. The terminal connecting member needs to contact the ribbon terminal uniformly when connecting to the ribbon terminal placed on the surface of the scraper shaped member. Therefore, it is the rectangular block in which plural movable conductive pins are provided.

The inspection apparatus terminal is connected to the ribbon terminal placed on the surface of the scraper shaped member while the base portion of the ribbon-shaped terminal extended from the backing material slit of the photovoltaic device panel is pressed by the pressing means 300 described in <4>. Preferably the terminal connecting means are provided by the same quantity as the ribbon terminal (which is two in this embodiment) and each terminal connecting means operate independently. However, one set of terminal connecting means may operate while two terminal connecting members are insulated each other for two ribbon terminals.

In the above-described embodiment, the cylinders are used as the actuator for performing the operations of the stand-up means 100, the pressing means 300, and the terminal connecting means 400. However, other linear actuators may be employed as the actuator, actuator not limited to cylinders.

<6> Operation of Ribbon Terminal Connecting Apparatus

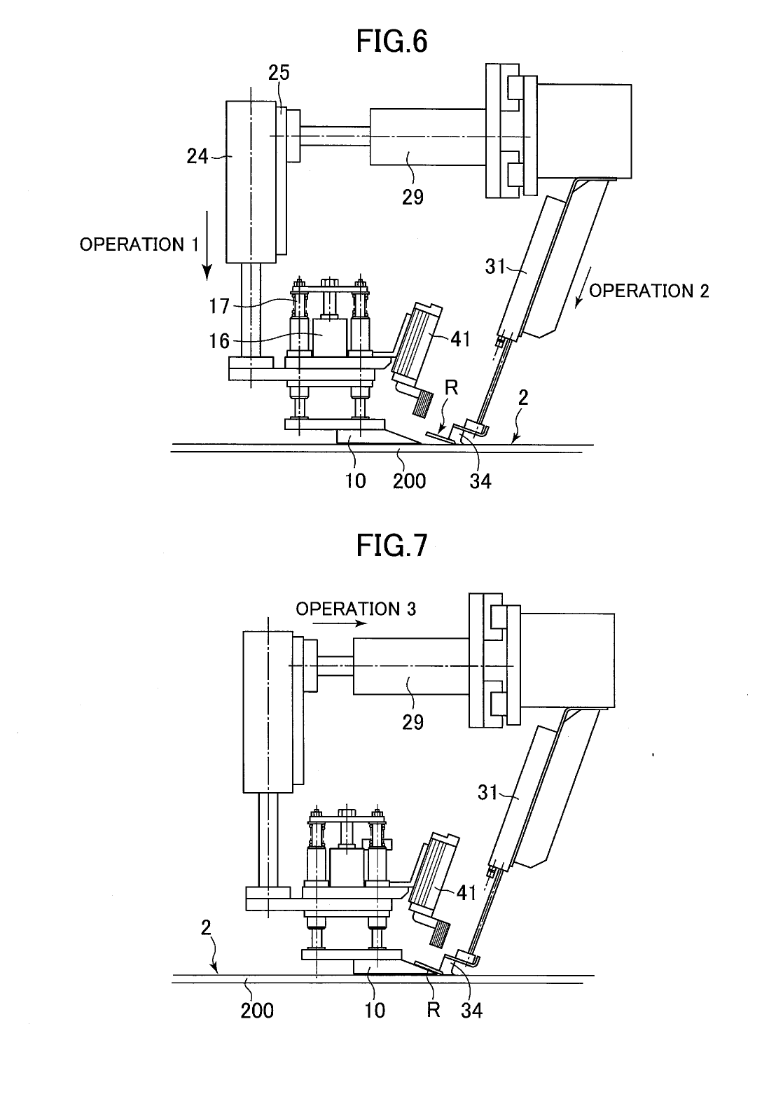

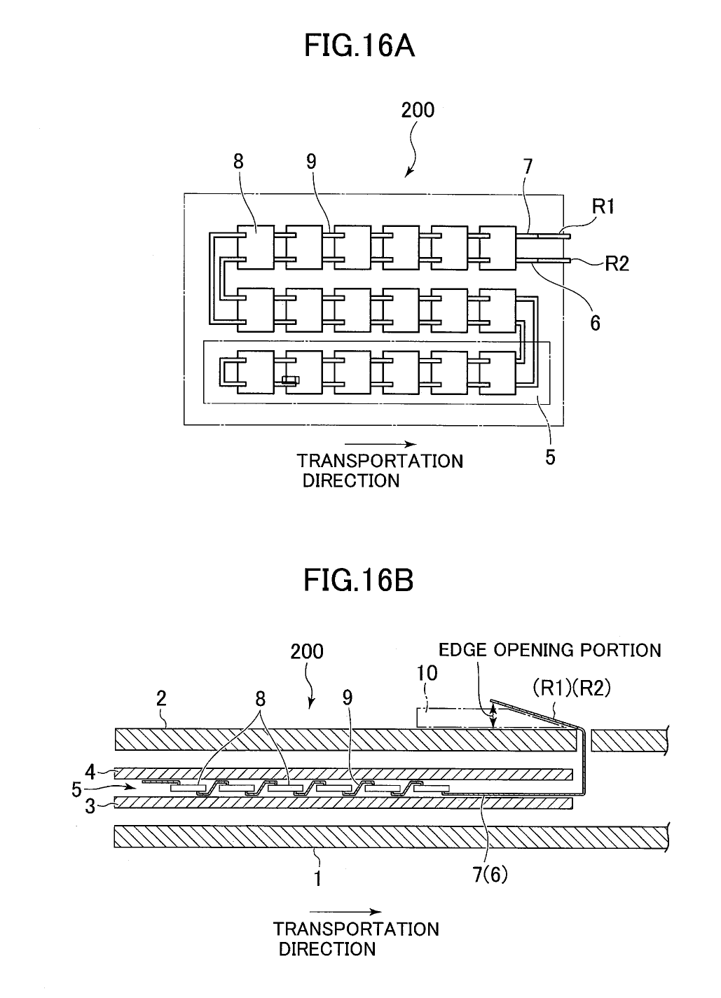

Next, a description is given of the operation in the above-described embodiment with reference to FIGS. 6, 7 and 8. As shown in FIG. 16A, the photovoltaic device panel 200 as the object to be measured of the present invention has the ribbon terminal R1 of the positive electrode side and the ribbon terminal R2 of the negative electrode side. Each ribbon terminal is connected to the inspection apparatus terminal as aftermentioned by using the above-described structure of the connecting unit U.

1) Initial State

FIG. 5 shows the state that the scraper shaped member 10 of the stand-up means is raised. Cylinders 16 and 24 in FIG. 5 are at the raised position.

2) Operation 1 (See FIG. 6)

The scraper shaped member is lowered toward the backing material of the photovoltaic device panel by the first ascent/descent cylinder 24 of the stand-up means until it reaches the certain distance from the backing material. After that, the scraper shaped member is lowered onto the surface of the backing material of the photovoltaic device panel by the second ascent/descent cylinder 24. Since the spring 17 shrinks during this operation, the pressing force of the second ascent/descent cylinder which the scraper shaped member applies to the photovoltaic device panel 200 is reduced. The impact is reduced or eliminated when the scraper shaped member lands on the surface of the backing material of the photovoltaic device panel. Therefore, neither damages nor cracks occur to photovoltaic cells when the scraper shaped member lands on the photovoltaic device panel.

3) Operation 2 (See FIG. 6)

After completing the operation 1, the ascent/descent cylinder 31 of the pressing means 300 is lowered to press the base portion of the ribbon terminal as shown in FIG. 9. In other words, the base portion of the ribbon terminal extended from the backing panel of the photovoltaic device panel is held down.

4) Operation 3 (See FIG. 7)

From the state in FIG. 6, the moving cylinder 29 of the stand-up means moves back. By this operation, the scraper shaped member landed on the backing material of the photovoltaic device panel moves toward the ribbon terminal while contacting the backing material. The ribbon terminal, which is in the state shown in FIG. 16B, is placed on the tapered surface of the scraper shaped member at the end of the backward movement of the cylinder 29. As described in the operation 1, the scraper shaped member moves smoothly on the surface of the backing material of the photovoltaic device panel due to a reduction effect of the pressing force by the ascent/descent mechanism.

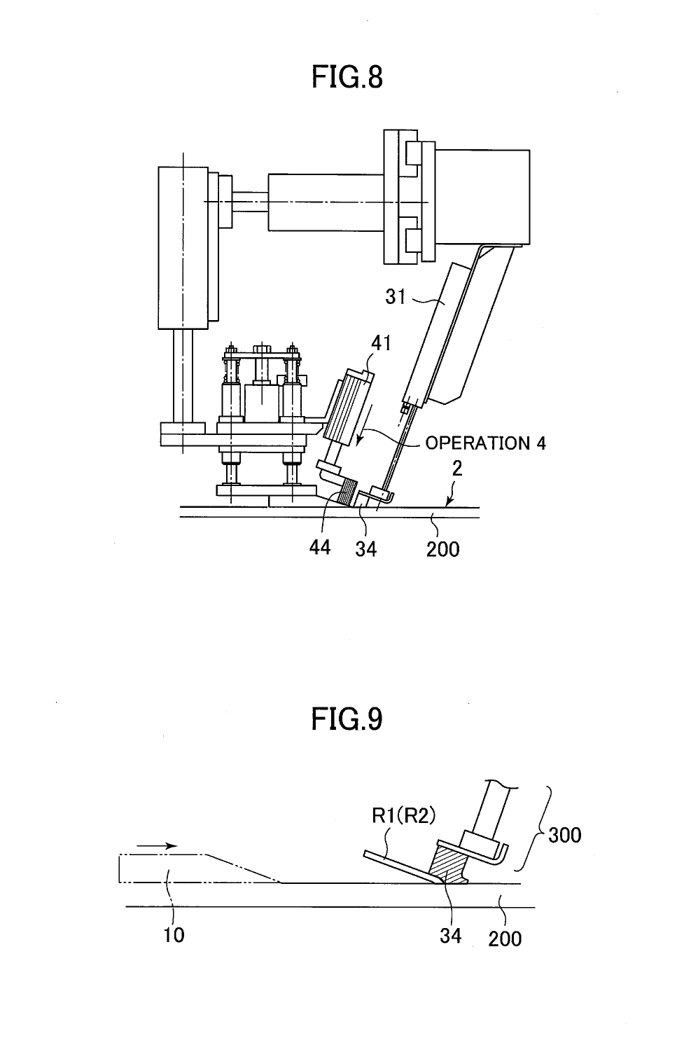

5) Operation 4 (See FIG. 8)

After completing the operation 3 in FIG. 7, the ascent/descent cylinder 41 of the terminal connecting means 400 is lowered. The terminal connecting member 44 attached to the end plate of the ascent/descent cylinder 41 is connected to the inspection apparatus terminal. Consequently, the ribbon terminal of the photovoltaic panel is connected to the inspection apparatus terminal.

Another ribbon terminal also is simultaneously connected to the inspection apparatus terminal by the operation 1 to 5. Herewith, the inspecting measurement of the photovoltaic device panel as the measurement object placed on the inspection apparatus A starts. After completing the inspection, the pressing means 300 and the terminal connecting means 400 ascends. The moving cylinder 29 of the stand-up means 100 moves forward. The first ascent/descent cylinder 24 100 and the second ascent/descent cylinder 16 of the stand-up means ascend. The state of the connecting unit U returns to an initial state 1).

### Second Embodiment

In the description of the operation of the embodiment 1, the scraper shaped member of the stand-up means 100 is lowered and lands on the surface of the backing material of the photovoltaic material. However, as shown in FIG. 16B, when there is apparently the opening edge between the ribbon terminal and the surface of the photovoltaic device panel, the ribbon terminal is placed on the tapered surface of the scraper shaped member by the following operations: the scraper shaped member is lowered toward the surface of the backing material while maintaining a gap between the scraper shaped member and the backing material of the photovoltaic device panel; and the moving cylinder 29 of the stand-up means moves back. Consequently, since the scraper shaped member does not land on the surface of the backing material of the photovoltaic device panel, no pressing force occurs to the photovoltaic device panel, and neither damages nor cracks occurs to photovoltaic cells.

### Third Embodiment

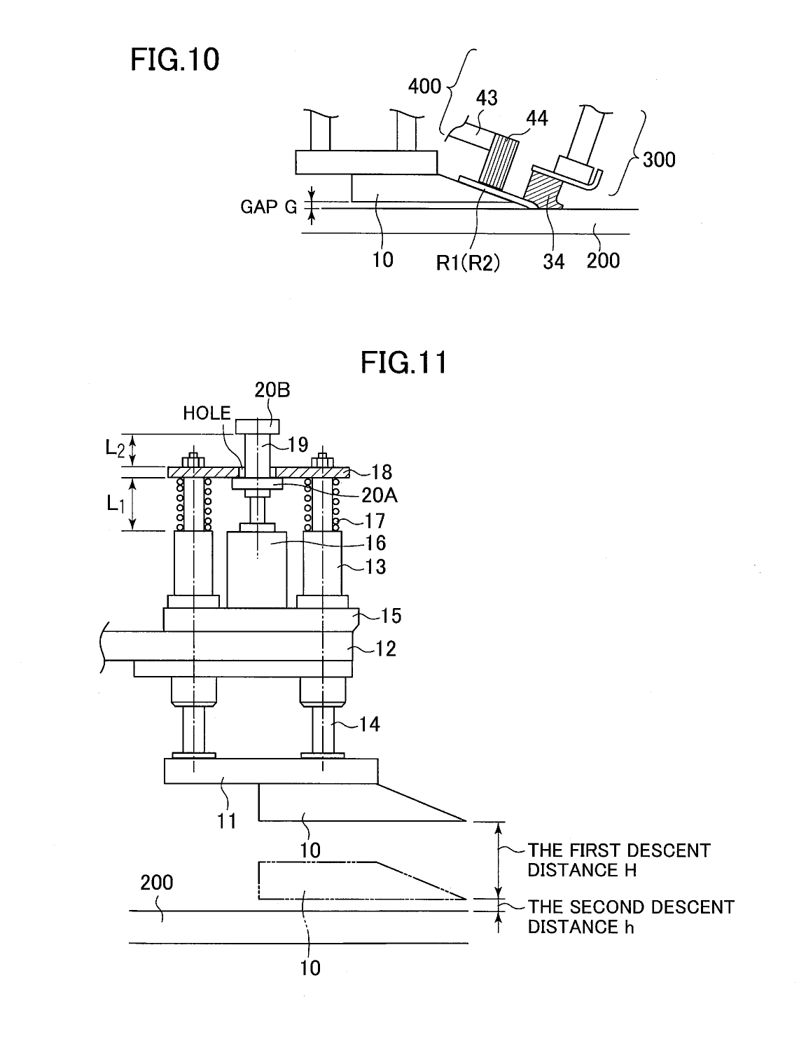

The third embodiment is as follows: the operation is added between Operation 3 and Operation 4 in <6> Operation of ribbon-shaped terminal connecting apparatus of the first embodiment; the added operation is that the scraper shaped member 10 of the stand-up means 100 is raised by very small distance from the backing material of the photovoltaic device panel. As shown in FIG. 10, although the terminal connecting member 44 of the terminal connecting means 400 lands on the ribbon-shaped terminal placed on the tapered surface of the scraper shaped member 10 by the next operation, no pressing force is applied to the backing material of the photovoltaic device panel. When the terminal connecting means 400 is pressed against the ribbon terminal, no impulsive force occurs the backing material of the photovoltaic device panel. Consequently, this can prevent damages or cracks to photovoltaic cells certainly.

The concrete method for adding the operation to the third embodiment is realized by changing the first or the second ascent/descent cylinder of the stand-up means 100 to a two-stage cylinder.

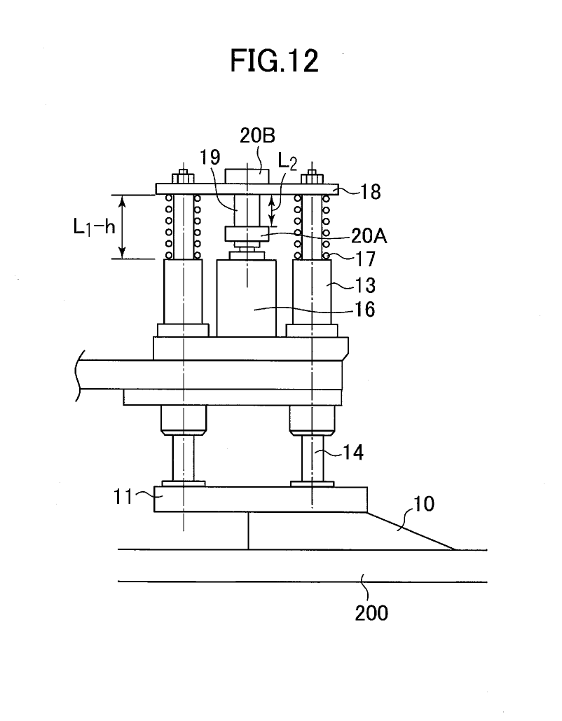

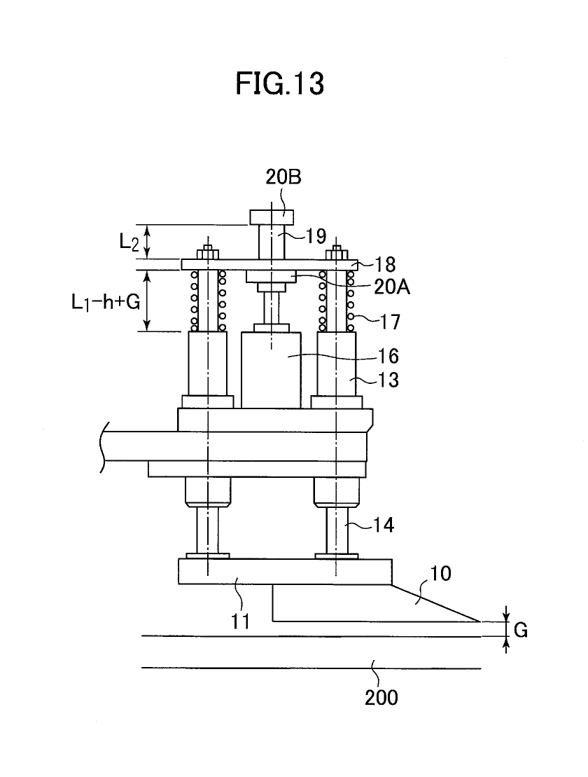

In addition, the operation of the third embodiment is realized by changing the configuration of the second ascent/descent portion in FIG. 5 to the configurations which are described in FIG. 11, FIG. 12 and FIG. 13. FIGS. 11 to FIG. 13 are the explanatory drawing of the portion which is different from FIG. 5. The other portion is the same configuration as in FIG. 5. A description is given with reference to FIG. 11 to FIG. 13. The bar 19 is provided to the tip of the rod of the second ascent/descent cylinder 16 by the pusher 20A. In addition, the stopper 20B is provided to the edge of the bar 19. In FIG. 5, since the rod of the cylinder 16 is connected to the end plate 18, the scraper shaped member ascends and descends with an ascent/descent operation of the cylinder 16. In FIG. 11, the end plate 18 has the hole which the bar 19 penetrates. The bar 19 and the tip of the cylinder 16 is connected by the pusher 20A.

FIG. 11 shows the state that the scraper shaped member 10 is raised (Initial state of the first embodiment). From this state, the first ascent/descent cylinder 24 in FIG. 5 lowers the scraper shaped member for the first descent H and the scraper shaped member reaches the position illustrated with the chain double-dashed line. Although the scraper shaped member is lowered to the position illustrated with the chain double-dashed line, the state of the second ascent/descent portion does not change. The scraper shaped member has two guide bars 14 guided by two guides 13. Two guide bars 14 are connected to the end plate 18. The spring 17 is disposed between the end plate 18 and the guide 13 in the state where the spring is not compressed. At this time, the cylinder 16 is raised and the pusher 20A is in contacted with the end plate. L1 shows the distance between the end plate 18 and the guide 13, L2 shows the distance between the end plate 18 and the stopper 20B. From this state, the scraper shaped member is lowered by the second ascent/descent cylinder 16 for the second descent distance h, and then lands on the surface of the backing material of the photovoltaic device panel. FIG. 12 shows the state that the scraper shaped member 10 lands on the surface of the backing material of the photovoltaic device panel. As shown in FIG. 12, after the cylinder 16 descends for the distance L2 and the stopper 20B contacts against the end plate 18, the cylinder 16 further descends for the distance h and the scraper shaped member is landed on the surface of the backing material of the photovoltaic device panel. In this state, the distance between the end plate 18 and the stopper 20B is (L2−h).

Since the first cylinder 24 in FIG. 5 is lowered to the downward end, when the scraper shaped member lands on the backing material of the photovoltaic device panel by the operation in FIG. 12, the force equal to the difference between the downward pressure of the cylinder 16 and the upward repulsive force by a compressive force of the spring 17 applies to the photovoltaic device panel as the pressing force. The pressing force becomes very slight by adjusting the spring constant of the spring, the bore diameter and air pressure of the cylinder.

FIG. 13 shows the state that the cylinder 16 ascends from a state of FIG. 12 for stroke L2. That is, the plate 18 is raised by the pusher 20A for stroke (L2+G). As a result, the gap G occurs between the scraper shaped member and the backing material of the photovoltaic device panel. The distance of the gap G is adjusted by either changing the thickness of the pusher 20A or inserting the ring-shaped plate into the upper part of the pusher 20A. In this state, the distance between the end plate 18 and the guide 13 is (L2−h+G).

### Fourth Embodiment

In the first embodiments to the third one, the ascent/descent operation of the stand-up means has the first ascent/descent operation and the second one. Each ascent/descent operation is performed by each cylinder (actuator). However, in this embodiment, the ascent/descent operation of the scraper shaped member 10 of the stand-up means is performed by one cylinder (actuator).

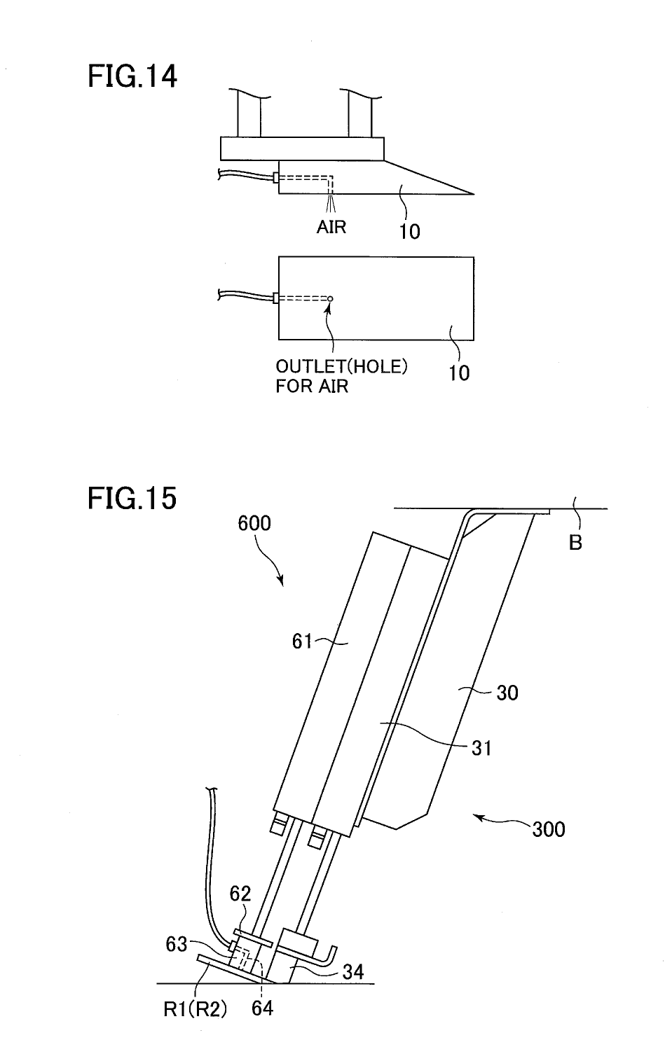

The scraper shaped member 10 is lowered rapidly by one cylinder. The control means is provided for detecting whether the scraper shaped member approaches the backing material. As shown in FIG. 14, the nozzle (hole) is provided as the control means. The air of constant pressure is spouted from the nozzle of the bottom surface of the scraper shaped member. When the scraper shaped member which has the nozzle approaches the surface of the backing material of the photovoltaic device panel, the backing pressure of the air spouted from the nozzle increases. When the backing pressure exceeds the predetermined value while detecting the change of this backing pressure, the descent operation of the cylinder stops.

Moreover, unlike the method of using the nozzle of the air, the following configuration is employed: the distance measuring sensor such as the laser sensor is provided to the mounting member of the scraper shaped member to detect the distance between the descending scraper shaped member and the backing material of a photovoltaic material; and then the movement stops when it reaches the predetermined position.

As described above, when the distance between the scraper shaped member and the backing material of the photovoltaic device panel became the certain distance (constant distance), the descent operation stops and the moving cylinder 29 of the stand-up means moves backwards. The ribbon terminal is placed on the tapered surface of the scraper shaped member by these operations. Therefore, since the scraper shaped member dose not land on the surface of the backing material of the photovoltaic device panel, no pressing force occurs to the photovoltaic device panel, and neither damages nor cracks occurs to the photovoltaic device panel.

The following configuration is employed: when the distance between the scraper shaped member and the back face of the photovoltaic device panel becomes equal to the predetermined distance (constant distance), the scraper shaped member lands on the back material of the photovoltaic device panel by switching the air-circuit of the elevating cylinder to the low pressure air-circuit with the conventional pressure modifying circuit. Consequently, the pressing force is reduced when the scraper shaped member lands on the surface of the backing material of the photovoltaic device panel.

In addition, these configurations enable the descent time of the stand-up means 100 to shorten. And the inspecting time of the photovoltaic device panel by the inspection apparatus A is reduced.

### Fifth Embodiment

As shown in FIG. 16B, when the dimension of the opening portion of a ribbon-shaped terminal is not large enough to be placed on the tapered surface of the scraper shaped member because of the material or the thickness of the ribbon-shaped terminal, the connecting unit U is configured as below. In this embodiment, the pressing means 300 is provided with the suction gripping means 600 as shown in FIG. 15.

As shown in FIG. 15, the sucking means 600 is configured as below. The cylinder 61 for an ascending/descending operation is disposed on the ascent/descent cylinder 31 of the pressing means 300. The guide cylinder is preferably employed as Cylinder, but Cylinder is not limited to the guide cylinder. The end plate 62 of the guide cylinder has the sucking member 63. The air sucking hole 64 is provided on the tip of the sucking member. When the sucking member 63 approaches the ribbon terminal with the cylinder 61, the ribbon terminal is sucked by the air from the air sucking hole to stand up.

In this embodiment, the pressing means operates before the moving cylinder 29 of the stand-up means 100 moves backwards (operation 3 in <5>). The sucking means 600 provided to the pressing means 300 operates and the ribbon terminal stands up. After that, the moving cylinder 29 moves backwards. Consequently, the ribbon terminal is placed on the tapered surface of the scraper shaped member.

By adding this sucking means, certainly the ribbon terminal stands up and is connected to the inspection apparatus terminal.

As many apparently widely different embodiments of the present invention can be made without departing from the spirit and scope thereof, it is to be understood that the invention is not limited to the specific embodiments thereof except as defined in the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A ribbon terminal connecting apparatus for connecting an inspection apparatus terminal to a ribbon terminal extended from a rear face of a backing material for a photovoltaic device panel, the ribbon terminal connecting apparatus comprising:
stand-up means for standing the ribbon terminal up on the backing material, comprising a stand-up member;
pressing means for pressing down on a base portion of the ribbon terminal;
terminal connecting means for connecting the inspection apparatus terminal; and
moving means for moving the stand-up member,
wherein the stand-up member of the stand-up means is lowered onto and contacted against the backing material of the photovoltaic device panel, the base portion of the ribbon terminal extended from the backing material is held down by the pressing means for pressing down on the base portion of the ribbon terminal, the moving means moves the stand-up member so that a leading edge of the ribbon terminal extending across the backing material is placed on the stand-up member, and the terminal connecting means connects the terminal of the inspection apparatus to the ribbon terminal placed on the stand-up member.

2. The ribbon terminal connecting apparatus according to claim 1, wherein, when the terminal connecting means connects the terminal of the inspection apparatus to the ribbon terminal placed on the stand-up member, the stand-up member is raised and separated from a surface of the backing material of the photovoltaic device panel.

3. The ribbon terminal connecting apparatus according to claim 1, further comprising control means provided to the stand-up member for detecting a position of the surface of the backing material, wherein, when the stand-up member is lowered onto the backing material of the photovoltaic device panel, the control means detects the position of the surface of the backing material and adjusts the pressure with which the stand-up member contacts the backing material.

4. A ribbon terminal connecting apparatus for connecting an inspection apparatus terminal to a ribbon terminal extended from a rear face of a backing material for a photovoltaic device panel, the ribbon terminal connecting apparatus comprising:
stand-up means for standing the ribbon terminal up on the backing material, comprising a stand-up member having control means for detecting a position of a surface of the backing material;
pressing means for pressing down on a base portion of the ribbon terminal;
terminal connecting means for connecting the inspection apparatus terminal; and
moving means for moving the stand-up member,
wherein, when the stand-up member of the stand-up means is lowered onto the backing material of the photovoltaic device panel, the control means of the stand-up member detects the position of the surface of the backing material and lowers the stand-up member toward the backing material while maintaining a gap between the stand-up member and the surface of the backing material, the base portion of the ribbon terminal extended from the backing material is held down by the pressing means for pressing down on the base portion of the ribbon terminal, the moving means moves the stand-up member so that a leading edge of the ribbon terminal extending across the backing material is placed on the stand-up member, and the terminal connecting means connects the terminal of the inspection apparatus to the ribbon terminal placed on the stand-up member.

5. The ribbon terminal connecting apparatus according to claim 1, further comprising lowering means for lowering the stand-up member onto the photovoltaic device panel having a first lowering unit and a second lowering unit,
wherein, after the first lowering unit lowers the stand-up member to a certain distance from the surface of the backing material and stops thereat, the second lowering unit lowers the stand-up member onto the backing material of the photovoltaic device panel.

6. The ribbon terminal connecting apparatus according to claim 5, wherein the second lowering unit comprises reduction means for reducing the force of the stand-up means when the stand-up member is lowered onto the backing material of the photovoltaic device panel.

7. The ribbon terminal connecting apparatus according to claim 1, wherein, the moving means is provided with a measuring means for measuring a moved distance to decide whether or not the ribbon terminal is placed on the stand-up member when the moving means moves the stand-up member so that a leading edge of the ribbon terminal extending across the backing material is placed on the stand-up member.

8. The ribbon terminal connecting apparatus according to claim 1, wherein a sucking member is provided to make the ribbon terminal stand up.

9. The ribbon terminal connecting apparatus according to claim 1, wherein the tip end of the stand-up member is tapered.
